(19) United States
(12) Patent Application Publication
(10) Pub. No.: US 2023/0052218 A1
(43) Pub. Date: Feb. 16, 2023

(54) METHOD OF SiC WAFER PROCESSING

(71) Applicant: GlobalWafers Co., Ltd., Hsinchu (TW)

(72) Inventors: Shih-Che Hung, Hsinchu (TW); Wen-Huai Yu, Hsinchu (TW); Wen-Ching Hsu, Hsinchu (TW)

(73) Assignee: GlobalWafers Co., Ltd., Hsinchu (TW)

(21) Appl. No.: 17/861,254

(22) Filed: Jul. 11, 2022

Related U.S. Application Data
(60) Provisional application No. 63/227,331, filed on Jul. 29, 2021.

(30) Foreign Application Priority Data
May 12, 2022 (TW) 111117812

(51) Int. Cl. H01L 21/02

(52) U.S. Cl. CPC H01L 21/02024

(57) ABSTRACT

Provided is a method of SiC wafer processing, and the method includes the following steps. A SiC wafer is provided, and the SiC wafer has a first surface and an opposing second surface. A fine grinding process is performed on the first surface and the second surface of the SiC wafer. A dry etching process is performed on the first surface and the second surface of the SiC wafer to make the roughness of the first surface and the second surface 2.5 nm or less. After the dry etching process, a polishing process is performed on the first surface and the second surface of the SiC wafer.

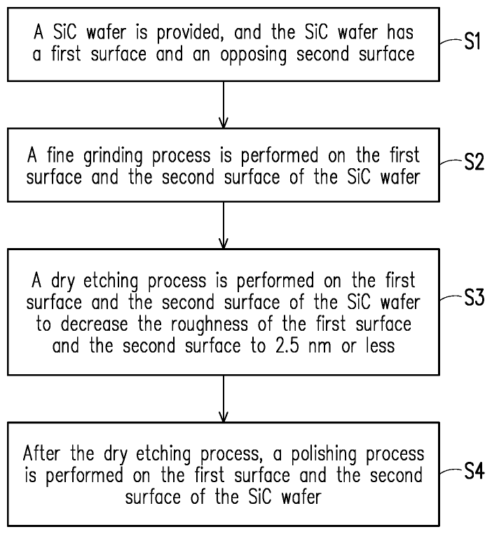

### CROSS-REFERENCE TO RELATED APPLICATION

This application claims the priority benefits of U.S. provisional application Ser. No. 63/227,331, filed on Jul. 29, 2021, and Taiwan application serial no. 111117812, filed on May 12, 2022. The entirety of each of the above-mentioned patent applications is hereby incorporated by reference herein and made a part of this specification.

### BACKGROUND

### Technical Field

The disclosure relates to a processing method, particularly to a method of SiC wafer processing.

### Description of Related Art

In the conventional processing of silicon carbide (SiC) wafers, the wafers undergo a polishing process after a grinding process. After the grinding process such as a fine grinding process, a residual damage layer is left on the surface of the SiC wafer, leaving the surface of the wafer rougher. To remove the damage layer, the subsequent polishing process usually removes a thickness of 1.5 μm or more from the wafer surface to meet the requirements. The conventional processing method also requires more polishing time to completely remove the damage layer caused by the polishing process. In this light, in addition to having a higher manufacturing cost, the conventional processing method also compromises the efficiency of operators.

Therefore, it is urgent to reduce the wafer manufacturing costs and save the polishing time at present.

### SUMMARY

The disclosure provides a method of SiC wafer processing capable of reducing the polishing removal amount, which thereby reduces the manufacturing cost of the wafer and/or the time required for the polishing process.

Some embodiments of the disclosure provide a method of SiC wafer processing including the following steps. A SiC wafer is provided, and the SiC wafer has a first surface and an opposing second surface. A fine grinding process is performed on the first surface and the second surface of the SiC wafer. A dry etching process is performed on the first surface and the second surface of the SiC wafer to make the roughness of the first surface and the second surface 2.5 nm or less. After the dry etching process, a polishing process is performed on the first surface and the second surface of the SiC wafer.

In some embodiments, the dry etching process is a reactive-ion etching (RIE) process, and the etching gas of the RIE process includes at least one or more selected from the group consisting of BCl₃, SF₆, O₂, and Ar.

In some embodiments, the etching parameters of the RIE process include gas flow rates of SF₆ set at a value within the range of 1 sccm to 80 sccm, O₂ set at a value within the range of 1 sccm to 20 sccm, and Ar set at a value within the range of 1 sccm to 80 sccm, an upper electrode set at a value within the range of 800 W to 2400 W, a lower electrode set at a value within the range of 30 W to 600 W, and a vacuum pressure set at a value within the range of 1 mtorr to 100 mtorr.

In some embodiments, after the dry etching process and prior to the polishing process, the roughness of the first surface is within the range of 1.7 nm to 2.2 nm, and the roughness of the second surface is within the range of 1.6 nm to 2.5 nm.

In some embodiments, during the dry etching process, the etching removal amount of the first surface is within the range of 2.5 μm to 3.5 μm, and the etching removal amount of the second surface is within the range of 2.5 μm to 3.5 μm.

In some embodiments, during the dry etching process, the etching removal amount of the first surface is within the range of 2.7 μm to 3.3 μm, and the etching removal amount of the second surface is within the range of 2.5 μm to 2.8 μm.

In some embodiments, the polishing process includes rough polishing and fine polishing.

In some embodiments, after the rough polishing and the fine polishing, the polishing removal amount of the first surface is 1.5 μm or less, and the polishing removal amount of the second surface is 1 μm or less.

In some embodiments, after the rough polishing and the fine polishing, the polishing removal amount of the first surface is within the range of 1.32 μm to 1.47 μm, and the polishing removal amount of the second surface is within the range of 0.55 μm to 0.75 μm.

In some embodiments, the scratch length of the first surface of the SiC wafer is within the range of 50 mm to 220 mm after the rough polishing.

In some embodiments, the time taken for the rough polishing and the fine polishing is 30 minutes or less.

Based on the above, according to the embodiment of the disclosure, the method of SiC wafer processing reduces the surface roughness of the wafer before the polishing process by the dry etching process. Accordingly, the polishing removal amount and the time required for the polishing process may be reduced in the subsequent polishing process.

### BRIEF DESCRIPTION OF THE DRAWING

The figure is a flow chart of a method of SiC wafer processing according to an embodiment of the disclosure.

### DESCRIPTION OF THE EMBODIMENTS

The figure is a flow chart of a method of SiC wafer processing according to an embodiment of the disclosure. In the figure, a SiC wafer is provided in step S1, and the SiC wafer has a first surface and an opposing second surface. The first surface is, for example, a silicon surface, and the second surface is, for example, a carbon surface. In some embodiments, the SiC wafer may be a SiC wafer formed by physical vapor transport, high temperature chemical vapor deposition, liquid epitaxy, and the like.

Please continue to refer to the figure. In step S2, a fine grinding process is performed on the first surface and the second surface of the SiC wafer. The purpose of the grinding process for SiC wafers is to achieve the desired thickness from the SiC wafers. In some embodiments, the average surface roughness (Ra) of the SiC wafer after the fine grinding process is greater than 2.5 nm.

Next, in step S3, a dry etching process is performed on the first surface and the second surface of the SiC wafer to make the roughness of the first surface and the second surface 2.5 nm or less. In some embodiments, the dry etching process may be a RIE process, and the etching gas of the RIE process may include at least one or more selected from the group consisting of BCl₃, SF₆, O₂, and Ar.

In some embodiments, the etching parameters of the RIE process include gas flow rates of SF₆ set at a value within a range of 1 sccm to 80 sccm, O₂ set at a value within a range of 1 sccm to 20 sccm, and Ar set at a value within a range of 1 sccm to 80 sccm; an upper electrode set at a value within a range of 800 W to 2400 W, a lower electrode set at a value within a range of 30 W to 600 W; and a vacuum pressure set at a value within a range of 1 mtorr to 100 mtorr. When the etching parameters are controlled within the above ranges, the etching removal amount may be prevented from being too large or too small to influent the surface roughness of the SiC wafer.

In some embodiments, during the dry etching process, the etching removal amount of the first surface (the silicon side) of the SiC wafer is within the range of 2.5 μm to 3.5 μm, or within the range of 2.7 μm to 3.3 μm. And the etching removal amount of the second surface (the carbon side) of the SiC wafer may be within the range of 2.5 μm to 3.5 μm, or within the range of 2.5 μm to 2.8 μm. An etching removal amount larger than the above ranges may lead to the formation of pits on the wafer surface, which requires an increased polishing removal amount in the subsequent polishing process to remove the defects generated on the wafer surface. In contrast, an etching removal amount less than the above ranges may hinder the damage layer caused by the fine grinding process from complete removal, and the polishing removal amount would need to be increased in the subsequent polishing process to fully remove the damage layer.

In some embodiments, after the dry etching process, the roughness of the first surface is within the range of 1.7 nm to 2.2 nm, and the roughness of the second surface is within the range of 1.6 nm to 2.5 nm. Reducing the surface roughness of the first surface and the second surface of the SiC wafer is able to reduce the polishing removal amount of the subsequent polishing process effectively, thereby reducing the polishing time required.

Next, in step S4, after the dry etching process, a polishing process is performed on the first surface and the second surface of the SiC wafer. In some embodiments, the polishing process includes rough polishing and fine polishing. Rough polishing includes, for example, single-sided polishing, and fine polishing includes, for example, double-sided polishing.

In some embodiments, after the rough polishing and the fine polishing, the polishing removal amount of the first surface (the silicon surface) is 1.5 μm or less, or within the range of 1.32 μm to 1.47 μm, and the polishing removal amount of the second surface is 1 μm or less, or within the range of 0.55 μm to 0.75 μm. In some embodiments, after the rough polishing, the scratch length of the first surface of the SiC wafer is controlled within a range of 50 mm to 220 mm.

In the embodiment of the disclosure, the time taken for the rough polishing and the fine polishing is 30 minutes or less. In the conventional wafer processing process, if polishing is directly performed after the fine grinding process without the dry etching process, the general time required for the polishing process is 60 minutes. By comparison, the time required for polishing after the dry etching process of the disclosure is reduced by half or more.

Based on the above conditions, the method of SiC wafer processing according to the embodiment of the disclosure reduces the surface roughness of the wafer before the polishing process, the polishing removal amount, and the time required for the polishing process. Therefore, the manufacturing cost of the polishing material may be reduced, and the efficiency may be improved.

Experimental examples are described as follows to prove that the method of SiC wafer processing of the disclosure is able to reduce the surface roughness of the wafer before the polishing process, the polishing removal amount, and the time required for the polishing process.

### Embodiment 1

In this embodiment, wafer 1-1 to wafer 1-3 were SiC wafers subjected to a fine grinding process and each had a silicon surface and an opposing carbon surface. The wafers in the embodiment each had different pre-etch thickness and different average surface roughness.

In this embodiment, the SiC wafer 1-1 to wafer 1-3 were provided, and a RIE process was then performed on the SiC wafer 1-1 to wafer 1-3 to etch their silicon and carbon surfaces. The etching parameters of the RIE process were set within the aforementioned ranges. The upper, middle, and average surface roughness of the etched wafer and the thickness of the etched wafer were subsequently measured. The results are shown in Table 1 below.

TABLE 1

| | | | | | | | | Wafer | Wafer | |
|---|---|---|---|---|---|---|---|---|---|---|
| | | | | | | | | thickness | thickness | |
| | | surface roughness (nm) | | | surface roughness (nm) | | | (μm) | (μm) | Removal |
| | | before etching | | | after etching | | | before | after | amount |
| | Embodiment 1 | upper | middle | average | upper | middle | average | etching | etching | (μm) |
| Silicon | wafer 1-1 | 3.47 | 4.03 | 3.75 | 2.55 | 1.40 | 1.98 | 367.33 | 364.09 | 3.24 |
| surface | wafer 1-2 | 3.48 | 3.10 | 3.29 | 2.29 | 1.26 | 1.78 | 367.41 | 364.68 | 2.74 |
| | wafer 1-3 | 3.54 | 2.86 | 3.20 | 2.6 | 1.64 | 2.12 | 367.62 | 364.75 | 2.87 |
| Carbon | wafer 1-1 | 3.73 | 3.14 | 3.44 | 1.99 | 2.79 | 2.39 | 364.09 | 361.75 | 2.34 |
| surface | wafer 1-2 | 3.05 | 2.52 | 2.79 | 3.48 | 1.48 | 2.48 | 364.68 | 362.34 | 2.34 |
| | wafer 1-3 | 2.57 | 2.63 | 2.60 | 1.81 | 1.43 | 1.62 | 364.75 | 362.04 | 2.71 |

As can be seen from Table 1 above, after the SiC wafer 1-1 to wafer 1-3 are subjected to the RIE process, the etching removal amount is controlled within an ideal range, and the average surface roughness is all 2.5 nm or less. The experimental results above show that the wafers subjected to the RIE process have less surface roughness before the polishing process.

### Embodiment 2

Described hereinafter is the etching parameter adjustment of the RIE process. In this embodiment, a SiC wafer was provided, and the SiC wafer was then subjected to a RIE process with different parameters shown in Table 2 below (see Embodiment 2-1 to Embodiment 2-4). For example, a SiC wafer was subjected to different gas sources, different ranges of gas flow, upper electrode, lower electrode and vacuum pressure are adopted, and the removal rates of the wafer surface by dry etching under different parameters were then measured. The results are shown in the following table 2.

TABLE 2

| | | | | | Upper | Lower | Vacuum | Removal |
|---|---|---|---|---|---|---|---|---|
| | Gas Source (sccm) | | | | electrode | electrode | pressure | Rate/Efficiency |
| Embodiment 2 | BCl₃ | SF₆ | O₂ | Ar | (W) | (W) | (mtorr) | Improvement |
| Embodiment 2-1 | 1~100 | N/A | 1~10 | 1~100 | 800~1600 | 60~100 | 1~100 | N/A |
| Embodiment 2-2 | N/A | 1~100 | 1~10 | 1~100 | 800~1600 | 60~100 | 1~100 | 300% |
| Embodiment 2-3 | N/A | 1~100 | 1~10 | 1~100 | 1600~2000 | 100~400 | 1~100 | 450% |
| Embodiment 2-4 | N/A | 1~100 | 10~30 | 1~100 | 1600~2400 | 100~400 | 1~100 | 600% |

It can be seen from Table 2 above that when the gas source includes SF₆, O₂, and Ar, the removal rate can be effectively improved compared with the use of BCl₃, O₂, and Ar. In addition, when the gas flow rate of O₂ is increased or the power of the upper electrode and the lower electrode is increased, the removal rate of the wafer surface by dry etching is improved, and the time required for the etching process is reduced, lowering the manufacturing costs.

### Embodiment 3

The SiC wafers of Embodiment 1 (wafer 1-1, wafer 1-2, and wafer 1-3) were provided and had been subjected to the RIE process as in Embodiment 1. Next, the SiC wafers were subjected to a polishing process (rough polishing and fine polishing) using wax, and the same two wafers were stacked together to avoid fragmentation during the polishing process. After the silicon surface and carbon surface of the SiC wafer were polished, the wafer thickness, the total thickness variation, the bow, and the total warpage were measured before and after polishing. The results are shown in Table 3 below.

TABLE 3

| | | | Total Thickness | | |
|---|---|---|---|---|---|
| Silicon | | Wafer Thickness | Variation | Bow | Total Warpage |
| Surface | Embodiment 3 | (CntThk) (μm) | (TTV) (gm) | (μm) | (TotWarp) (μm) |
| before | wafer 1-1 | 825.78 | 4.60 | 9.08 | 19.51 |
| polishing | wafer 1-2 | 825.29 | 3.96 | 12.94 | 32.97 |
| | wafer 1-3 | 825.13 | 3.89 | 6.28 | 22.50 |
| after | wafer 1-1 | 824.46 | 4.48 | −4.94 | 17.86 |
| polishing | wafer 1-2 | 823.91 | 4.27 | −2.05 | 14.14 |
| | wafer 1-3 | 823.66 | 3.66 | −3.91 | 15.80 |
| difference | wafer 1-1 | 1.32 | 0.12 | 14.02 | 1.66 |
| A | wafer 1-2 | 1.37 | −0.31 | 14.98 | 18.83 |
| | wafer 1-3 | 1.47 | 0.23 | 10.19 | 6.70 |
| before | wafer 1-1 | 824.18 | 4.27 | 12.76 | 37.66 |
| polishing | wafer 1-2 | 825.24 | 3.63 | 15.55 | 34.69 |
| | wafer 1-3 | 824.43 | 4.22 | 7.84 | 20.76 |
| after | wafer 1-1 | 823.63 | 4.11 | 10.36 | 31.68 |
| polishing | wafer 1-2 | 824.49 | 3.64 | 14.38 | 35.40 |
| | wafer 1-3 | 823.68 | 3.57 | 6.41 | 19.21 |
| difference | wafer 1-1 | 0.55 | 0.16 | 2.40 | 5.98 |
| A | wafer 1-2 | 0.75 | −0.01 | 1.17 | −0.71 |
| | wafer 1-3 | 0.75 | 0.65 | 1.43 | 1.56 |

It can be seen from Table 3 above that the polishing removal amount of the silicon surface of the SiC wafer after dry etching was 1.5 μm or less, and the polishing removal amount of the carbon surface was 1 μm or less. Compared with the 1.5 μm-or-more polishing removal amount of both carbon surface and silicon surface of a wafer without dry etching in the conventional process, the polishing removal amount required for the dry etching SiC wafer of the disclosure is relatively low, which saves costs and polishing time effectively. In addition, after rough polishing, the scratch lengths of the silicon surfaces of wafer 1-1 to wafer 1-3 were within the range of 64 mm to 202 mm, and the bow and the total warpage thereof also met the requirements.

In summary, the method of SiC wafer processing according to the embodiments of the disclosure is able to reduce the surface roughness of a wafer before the polishing process through the dry etching process, such that the polishing removal amount and the time required for the polishing process may be reduced in the subsequent polishing process. Therefore, the manufacturing cost of the polishing material may be reduced, and the efficiency may be improved.

What is claimed is:

1. A method of SiC wafer processing, comprising:
providing a SiC wafer having a first surface and an opposing second surface;
performing a fine grinding process on the first surface and the second surface of the SiC wafer;
performing a dry etching process on the first surface and the second surface of the SiC wafer to make a roughness of the first surface and the second surface 2.5 nm or less; and
after the dry etching process, performing a polishing process on the first surface and the second surface of the SiC wafer.

2. The method according to claim 1, wherein the dry etching process is a reactive-ion etching process, and an etching gas of the reactive-ion etching process comprises at least one or more selected from the group consisting of BCl₃, SF₆, O₂, and Ar.

3. The method according to claim 2, wherein etching parameters of the reactive-ion etching process comprise: gas flow rates of SF₆ set at a value within a range of 1 sccm to 80 sccm, O₂ set at a value within a range of 1 sccm to 20 sccm, and Ar set at a value within a range of 1 sccm to 80 sccm; an upper electrode set at a value within a range of 800 W to 2400 W, a lower electrode set at a value within a range of 30 W to 600 W; and a vacuum pressure set at a value within a range of 1 mtorr to 100 mtorr.

4. The method according to claim 1, wherein after the dry etching process and prior to the polishing process, a roughness of the first surface is within a range of 1.7 nm to 2.2 nm, and a roughness of the second surface is within a range of 1.6 nm to 2.5 nm.

5. The method according to claim 1, wherein during the dry etching process, an etching removal amount of the first surface is within a range of 2.5 μm to 3.5 μm, and an etching removal amount of the second surface is within a range of 2.5 μm to 3.5 μm.

6. The method according to claim 5, wherein during the dry etching process, an etching removal amount of the first surface is within a range of 2.7 μm to 3.3 μm, and an etching removal amount of the second surface is within a range of 2.5 μm to 2.8 μm.

7. The method according to claim 1, wherein the polishing process comprises rough polishing and fine polishing.

8. The method according to claim 7, wherein after the rough polishing and the fine polishing, a polishing removal amount of the first surface is 1.5 μm or less, and a polishing removal amount of the second surface is 1 μm or less.

9. The method according to claim 8, wherein after the rough polishing and the fine polishing, a polishing removal amount of the first surface is within a range of 1.32 μm to 1.47 μm, and a polishing removal amount of the second surface is within a range of 0.55 μm to 0.75 μm.

10. The method according to claim 7, wherein a scratch length of the first surface of the SiC wafer is within a range of 50 mm to 220 mm after the rough polishing.

11. The method according to claim 7, wherein a time taken for the rough polishing and the fine polishing is 30 minutes or less.
